(19) United States
(12) Patent Application Publication
(10) Pub. No.: US 2011/0233058 A1
(43) Pub. Date: Sep. 29, 2011

(54) Magnetron Plasma Sputtering Apparatus

(76) Inventor: Cheng-Tsung Liu, Kaohsiung (TW)

(21) Appl. No.: 12/944,907

(22) Filed: Nov. 12, 2010

(30) Foreign Application Priority Data
Mar. 26, 2010 (TW) 099109191

(51) Int. Cl. C23C 14/35

(52) U.S. Cl. 204/298.16

(57) ABSTRACT

A magnetron plasma sputtering apparatus includes a sputtering chamber having a loading portion and an engaging portion opposite to the loading portion. A substrate is mounted to the loading portion. A target is mounted to the engaging portion. A sputtering space is defined between the loading portion and the engaging portion. A reference line extends through the loading portion, the sputtering space, and the engaging portion in sequence. A guiding coil surrounds the sputtering space with the reference line located in the center. A magnetron device is located at a side of the sputtering chamber adjacent to the engaging portion. The magnetron device has a magnetization side facing the engaging portion.

### BACKGROUND OF THE INVENTION

1. Field of the Invention

The present invention relates to a magnetron plasma sputtering apparatus and, more particularly, to a magnetron plasma sputtering apparatus that proceeds with plasma sputtering through magnetic control.

2. Description of the Related Art

A magnetron plasma sputtering apparatus generally affects charged particles with a magnetic field to effectively impact a target. The atoms on a surface of the target exchange with kinetic energy with the high-energy charged particles to generate ion sputtering. The ions flying away from the target results in the impact deposit on a substrate to form a film.

FIGS. 1 and 2 show a conventional magnetron plasma sputtering apparatus 9 including a sputtering chamber 91 and a magnetron 92. The sputtering chamber 91 includes a loading portion 911 and an engaging portion 912 opposite to the loading portion 911. An anode plate 913 is mounted to the loading portion 911, and a substrate 8 is mounted to the anode plate 913. A cathode plate 914 is mounted to the engaging portion 912, and a target 7 is mounted to the cathode plate 914. The anode plate 913 and the cathode plate 914 are respectively connected to positive and negative poles of a DC power source VDC.

The magnetron device 92 is located adjacent to the engaging portion 912 and creates a magnetic field to control ion sputtering of the target 7. The magnetron device 92 includes a primary magnet 921, an outer, annular magnet 922, and a yoke iron 923. The primary magnet 921 is mounted on an engagement face of the yoke iron 923. The annular magnet 922 is mounted around the primary magnet 921 and also mounted on the engagement face of the yoke iron 923. With reference to FIG. 2, the magnetic lines of force generated by the primary magnet 921 and the annular magnet 922 form closed magnetic paths C. The magnetic lines of force pass through the target 7. Thus, ion sputtering is generated when the atoms on the surface of the target 7 are impacted by charged particles, performing sputtering on the substrate 8.

However, some of the ions may not be able to reach the substrate 8 and shift from the sputtering path due to insufficient momentum. The sputtering operation on the substrate 8 cannot be achieved, resulting in low yield of the magnetron plasma sputtering apparatus 9. Improvement on the magnetron plasma sputtering apparatus 9 is thus required.

### SUMMARY OF THE INVENTION

The primary objective of the present invention is to provide a magnetron plasma sputtering apparatus that includes a guiding coil between a target and a substrate to enhance the overall sputtering effect of the magnetron plasma sputtering apparatus.

A magnetron plasma sputtering apparatus according to the present invention includes a sputtering chamber having a loading portion and an engaging portion opposite to the loading portion. A substrate is adapted to be mounted to the loading portion. A target is adapted to be mounted to the engaging portion. A sputtering space is defined between the loading portion and the engaging portion. A reference line extends through the loading portion, the sputtering space, and the engaging portion in sequence. A guiding coil surrounds the sputtering space with the reference line located in the center. A magnetron device is located at a side of the sputtering chamber adjacent to the engaging portion. The magnetron device has a magnetization side facing the engaging portion.

The present invention will become clearer in light of the following detailed description of illustrative embodiments of this invention described in connection with the drawings.

### BRIEF DESCRIPTION OF THE DRAWINGS

The illustrative embodiments may best be described by reference to the accompanying drawings where:

FIG. 1 shows a schematic view of a conventional magnetron plasma sputtering apparatus.

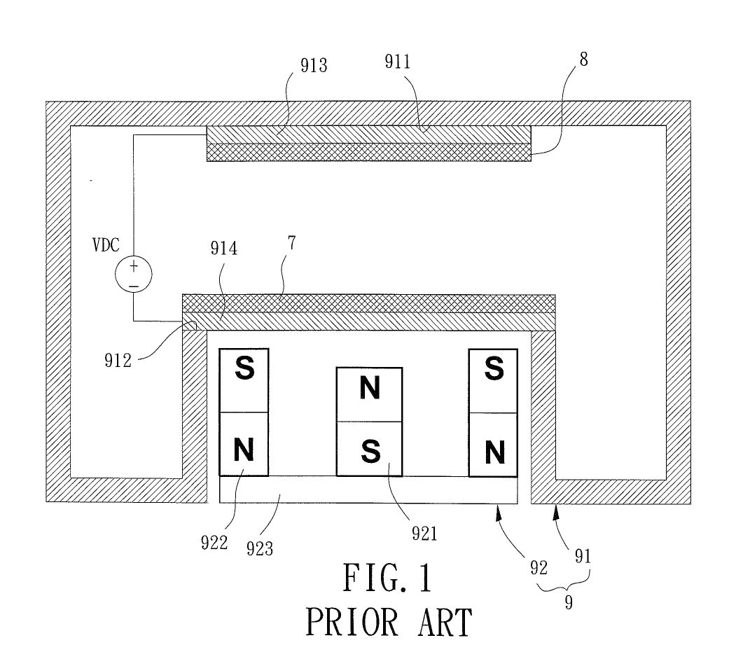

FIG. 2 shows a schematic view illustrating action of a magnetic field created by a magnetron device on a target of the magnetron plasma sputtering apparatus of FIG. 1.

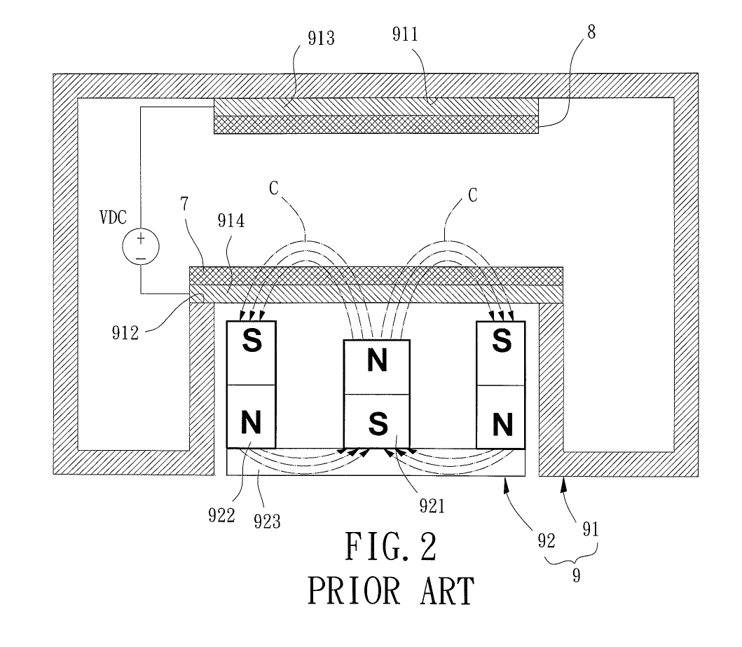

FIG. 3 shows a schematic view of a magnetron plasma sputtering apparatus according to the present invention.

FIG. 4 shows a schematic view illustrating action of a magnetic field created by a magnetron device on a target and action of a magnetic field created by a guiding coil of the magnetron plasma sputtering apparatus of FIG. 3.

All figures are drawn for ease of explanation of the basic teachings of the present invention only; the extensions of the figures with respect to number, position, relationship, and dimensions of the parts to form the preferred embodiments will be explained or will be within the skill of the art after the following teachings of the present invention have been read and understood. Further, the exact dimensions and dimensional proportions conforming to specific force, weight, strength, and similar requirements will likewise be within the skill of the art after the following teachings of the present invention have been read and understood.

Where used in the various figures of the drawings, the same numerals designate the same or similar parts. Furthermore, when the terms “first”, “second”, “side”, “portion”, “annular”, “width”, and similar terms are used herein, it should be understood that these terms refer only to the structure shown in the drawings as it would appear to a person viewing the drawings and are utilized only to facilitate describing the invention.

### DETAILED DESCRIPTION OF THE INVENTION

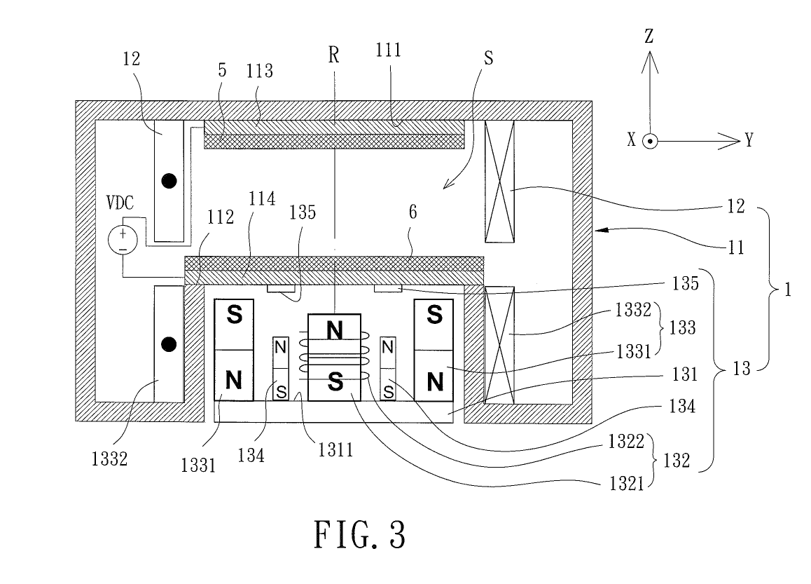

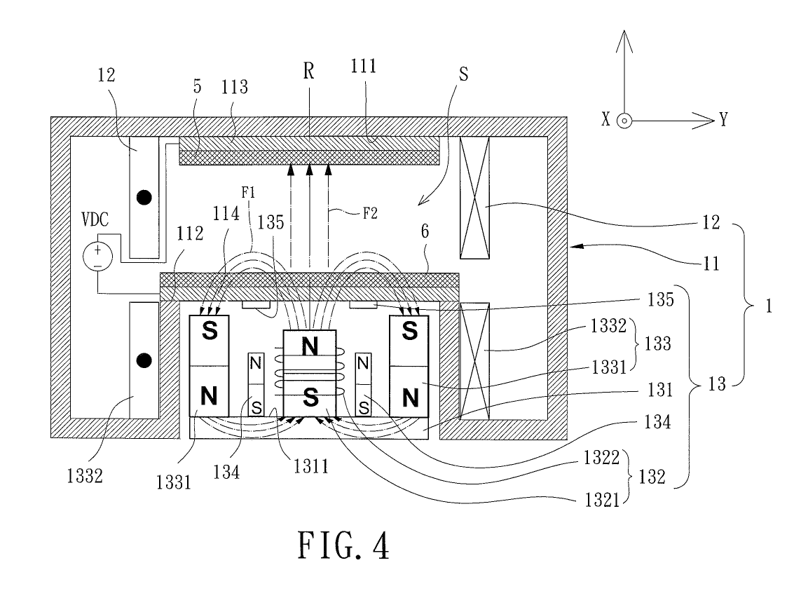

A magnetron plasma sputtering apparatus 1 of a preferred embodiment according to the present invention is shown in FIGS. 3 and 4. The magnetron plasma sputtering apparatus 1 is adapted to receive a target 6 for performing sputtering on a substrate 5. The magnetron plasma sputtering apparatus 1 includes a sputtering chamber 11, a guiding coil 12, and a magnetron device 13. The sputtering chamber 11 includes a loading portion 111 and an engaging portion 112 opposite to the loading portion 111. The engaging portion 112 is spaced from the loading portion 111 in a first direction Z. An anode plate 113 is mounted to the loading portion 111, and the substrate 5 is mounted to the anode plate 113. A cathode plate 114 is mounted to the engaging portion 112, and the target 6 is mounted to the cathode plate 114. The anode plate 113 and the cathode plate 114 are respectively connected to positive and negative poles of a DC power source VDC. A sputtering space S is defined between the loading portion 111 and the engaging portion 112. The sputtering chamber 11 defines a reference line R extending through a center of the sputtering chamber 11. The reference line R extends through the loading portion 113, the sputtering space S, and the engaging portion 112 in sequence.

The guiding coil 12 is mounted around the reference line R with the reference line R in the center. The guiding coil 12 surrounds the sputtering space S. Specifically, the guiding coil 12 is mounted to the loading portion 111 and surrounds the anode plate 114 and the sputtering space S, as shown in FIG. 3.

The guiding coil 12 includes an input connected to an external power source such that the guiding coil 12 can be energized by the external power source to create magnetic lines of force. The direction of the magnetic lines of force is identical to the direction of ion sputtering from the target 6 to the substrate 5. By such an arrangement, the ions flying away from the target 6 can stably move to the substrate 5 for sputtering operation under the guidance of the guiding coil 12.

Preferably, the sputtering chamber 11 is not magnetically conductive to avoid adverse effect on the function of the guiding coil 12.

Still referring to FIG. 3, the magnetron device 13 of the preferred embodiment of the present invention is located at a side of the sputtering chamber 11 adjacent to the engaging portion 112. The magnetron device 13 includes a magnetization side and a magnetically conductive side that are on opposite sides of the magnetron device 13. The magnetization side faces the target 6. The magnetron device 13 includes a yoke iron 131, a primary magnetic control member 132, an outer, annular magnetic control member 133, and a compensatory magnetic control member 134.

The yoke iron 131 is located on the magnetization side of the magnetron device 13 and includes a loading face 1311. The primary magnetic control member 132 is mounted on the loading face 1311 of the yoke iron 131. The primary magnetic control member 132 includes a permanent magnet 1321 and an electromagnetic coil 1322. The permanent magnet 1321 includes an engaging face for engaging with the loading face 1311. Thus, the permanent magnet 1321 can be mounted to the loading face 1311 with the permanent magnet 1321 located in a center of the loading face 1311. The permanent magnet 1321 further includes a magnetization face opposite to the engaging face. The magnetization face of the permanent magnet 1321 faces the target 6, providing a suitable electromagnetic field for the target 6 during ion sputtering. The electromagnetic coil 1322 is mounted around the permanent magnet 1321 and includes an input electrically connected to an external power source. The primary magnetic control member 132 can be controlled to increase or decrease the magnetization effect through control of the external power source.

The annular magnetic control member 133 is also mounted to the loading face 1311 of the yoke iron 131 and surrounds the primary magnetic control member 132. The annular magnetic control member 133 includes an annular magnet 1331 and an annular electromagnetic coil 1332. The annular magnet 1331 includes an engaging face engaged with the loading face 1311 of the yoke iron 131. The annular magnet 1331 further includes a magnetization face opposite to the engaging face of the annular magnet 1331 and facing the target 6. The annular electromagnetic coil 1332 is mounted around the annular magnet 1331. A wire winding direction of the annular electromagnetic coil 1332 is the same as that of the guiding coil 12. The annular electromagnetic coil 1332 includes an input electrically connected to an external power source to control the magnetron device 13 for controlling the magnetic flux in the first direction Z such that the magnetic flux is zero in a position where the target 6 has the deepest etching depth.

Still referring to FIG. 3, the compensatory magnetic control member 134 of the preferred embodiment of the present invention surrounds the primary magnetic control member 132 and is preferably located in the middle between the permanent magnet 1321 and the annular magnet 1331. The magnetic flux of the target 6 in a second direction Y perpendicular to the first direction Z can be increased by the compensatory magnetic control member 134 to increase the etching width of the target 6, enhancing the efficacy of the target 6. The compensatory magnetic control member 134 can be a magnet.

The magnetron device 13 of the preferred embodiment of the present invention further includes an annular iron ring 135 mounted to, and in intimate contact with, a surface of the target 6 facing the substrate 5. Alternatively, the annular iron ring 135 can be mounted to the other surface of the target facing the magnetization face of the permanent magnet 1321. The iron ring 135 is electromagnetically conductive to guide the magnetic flux of the permanent magnet 1321 and the annular magnet 1331 to flow in the second direction Y to the surface of the target 6, further increasing the etching width of the target 6.

FIG. 4 shows sputtering operation of the magnetron plasma sputtering apparatus 1 on the substrate 5 according to the present invention. The magnetron device 13 creates a magnetic field F1 to accelerate the charged particles impacting the target 6, causing the sputtering of the ions on the surface of the target 6 towards the substrate 5. At this time, the guiding coil 12 is energized by the external power source and creates magnetic flux F2 having a direction identical to the sputtering direction of the ions. The ions are guided by the magnetic flux F2 and smoothly deposited on the substrate 5 to form a film.

Conclusively, the overall sputtering effect of the magnetron plasma sputtering apparatus 1 according to the present invention is enhanced by the guiding coil 12.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A magnetron plasma sputtering apparatus comprising:
a sputtering chamber including a loading portion and an engaging portion opposite to the loading portion, with a substrate adapted to be mounted to the loading portion, with a target adapted to be mounted to the engaging portion, with a sputtering space defined between the loading portion and the engaging portion, with a reference line extending through the loading portion, the sputtering space, and the engaging portion in sequence;
a guiding coil surrounding the sputtering space with the reference line located in the center; and
a magnetron device located at a side of the sputtering chamber adjacent to the engaging portion, with the magnetron device having a magnetization side facing the engaging portion.

2. The magnetron plasma sputtering apparatus as claimed in claim 1, further comprising: an anode plate having a first side engaged with the loading portion and a second side, with the target adapted to be mounted to the second side of the anode plate; and a cathode plate including a first side engaged with the loading portion and a second side, with the target adapted to be mounted on the second side of the cathode plate.

3. The magnetron plasma sputtering apparatus as claimed in claim 2, with the guiding coil mounted to the loading portion.

4. The magnetron plasma sputtering apparatus as claimed in claim 3, with the guiding coil surrounding the anode plate.

5. The magnetron plasma sputtering apparatus as claimed in claim 1, with the sputtering chamber being not electromagnetically conductive.
